(19) United States
(12) Patent Application Publication
(10) Pub. No.: US 2026/0142496 A1
(43) Pub. Date: May 21, 2026

(54) Thunderstorm Activity Observation and Management System Applicable to Power Transmission Channel

(71) Applicant: Guizhou Power Grid Co., Ltd., Guiyang (CN)

(72) Inventors: Qianyong LV, Guiyang (CN); Guangze OUYANG, Guiyang (CN); Qiansu LV, Guiyang (CN); Zhukui TAN, Guiyang (CN); Xun ZHANG, Guiyang (CN); Lei FU, Guiyang (CN); Xianyin MAO, Guiyang (CN); Huan HUANG, Guiyang (CN); Peilong CHEN, Guiyang (CN); Qi YANG, Guiyang (CN); Mian WANG, Guiyang (CN); Yu SHEN, Guiyang (CN); Yong GAO, Guiyang (CN); Zongguo ZHOU, Guiyang (CN); Yu WU, Guiyang (CN); Diao ZOU, Guiyang (CN); Shouchang WU, Guiyang (CN); Rongjun HU, Guiyang (CN); Yizhao ZHANG, Guiyang (CN); Xiaodong REN, Guiyang (CN); Wei NIU, Guiyang (CN); Jianrong WU, Guiyang (CN); Qili ZHANG, Guiyang (CN); Jinke LU, Guiyang (CN); Yanxun WEI, Guiyang (CN); Zeyu OUYANG, Guiyang (CN); Jufeng JIN, Guiyang (CN); Xiao ZHANG, Guiyang (CN); Xinglong SHENG, Guiyang (CN)

(21) Appl. No.: 19/446,773

(22) Filed: Jan. 12, 2026

Related U.S. Application Data
(63) Continuation of application No. PCT/CN2024/134033, filed on Nov. 23, 2024.

(30) Foreign Application Priority Data
Nov. 23, 2023 (CN) 202311578966.9

(51) Int. Cl. H02J 13/12; G01R 19/165; G01R 31/08; G01W 1/10; H02J 3/0012; H02J 103/30

(52) U.S. Cl. CPC H02J 13/12; G01R 19/16528; G01R 31/085; G01W 1/10; H02J 3/0012; H02J 2103/30

(57) ABSTRACT

The present application provides a thunderstorm activity observation and management system and method applicable to a power transmission channel. The method comprises: acquiring the number of thunderstorm days in each analysis period; respectively adjusting combined with a preset discrepancy threshold so as to obtain a thunderstorm intensity value of each analysis period; determining a voltage intensity coefficient for each analysis period according to line feature data of a power transmission channel acquired in each thunderstorm activity; and determining a thunderstorm activity assessment value according to the above two result values, wherein the thunderstorm activity assessment value is used for determining a defense level, thereby, defense resources can be scientifically allocated according to the defense level.

### CROSS-REFERENCE TO RELATED APPLICATIONS

The present application is a continuation of International Application No. PCT/CN2024/134033, filed on Nov. 23, 2024, which claims priority to Chinese Patent Application No. 202311578966.9, filed on Nov. 23, 2023, the entire disclosure of which is incorporated herein by reference.

### TECHNICAL FIELD

The present application relates to the technical field of thunderstorm observation, and in particular to a thunderstorm activity observation and management system applicable to a power transmission channel.

### BACKGROUND

Thunderstorms are a localized and intense convective weather phenomenon that occurs in tropical and temperate regions. Thunderstorms are often accompanied by thunder, intense lightning, strong winds and heavy precipitation, such as heavy rain or hail. Meanwhile, thunderstorms are accompanied by heavy rainfall, resulting in a large amount of precipitation in a short period of time, which may cause floods and other disasters. The formation and development of thunderstorms can cause the weather to change rapidly, potentially bringing about severe impacts. In some cases, multiple thunderstorms can combine to form a mesoscale convective system, which further strengthens and expands the impact area. These large-scale convective systems may cause severe meteorological disasters such as floods, mudslides and heavy rainstorms. Therefore, understanding the characteristics and patterns of thunderstorms, and taking timely preventive and protective measures accordingly, is of vital importance in reducing the impact of disasters caused by thunderstorms.

The current observation and management methods for thunderstorm activities have certain limitations. One is that it is impossible to monitor and analyze the intensity of thunderstorm prevention based on the historical data of thunderstorms in ultra-high voltage transmission channels. This means that it is impossible to obtain sufficient information from past observational data to assess the intensity and development trend of future thunderstorms, which poses difficulties in implementing targeted thunderstorm prevention measures for different regions with varying terrain. Due to the limitations of conventional methods, the thunderstorm defense resources cannot be allocated scientifically either.

### SUMMARY

The present application aims to solve at least one of the technical defects above, particularly the technical defect that in the prior art thunderstorm defense resources are not scientifically allocated.

On a first aspect, the present application provides a thunderstorm activity observation and management method applicable to a power transmission channel, including:
acquiring the number of thunderstorm days in each analysis period based on multiple analysis periods preset, and counting and calculating the number of thunderstorm days in each analysis period so as to obtain a counting result, wherein the counting result is used for indicating the numerical discrepancy of the number of thunderstorm days in each analysis period;
adjusting the number of thunderstorm days of each analysis period according to the counting result and a preset discrepancy threshold so as to obtain a thunderstorm intensity value of each analysis period, wherein the thunderstorm intensity value is the number of thunderstorm days after adjustment in each analysis period;
acquiring multiple line feature data of the power transmission channel in each thunderstorm activity process in each analysis period;
determining a voltage intensity coefficient of the analysis period for each analysis period according to the line feature data of the analysis period, wherein the voltage intensity coefficient is used for indicating the thunderstorm intensity in the analysis period; and
determining a thunderstorm activity assessment value of each analysis period according to the thunderstorm intensity value and the voltage intensity coefficient of each analysis period, wherein the thunderstorm activity assessment is used for determining a defense level.

In one embodiment, the adjusting the number of thunderstorm days of each analysis period according to the counting result and a preset discrepancy threshold so as to obtain a thunderstorm intensity value of each analysis period includes:
comparing the counting result with the discrepancy threshold so as to determine whether the counting result exceeds the discrepancy threshold or not;
if so, performing product calculation on a preset proportion coefficient with the number of thunderstorm days of each analysis period respectively, and taking the obtained product value as the thunderstorm intensity value of each analysis period; and
if not, taking the number of thunderstorm days of each analysis period as the thunderstorm intensity value of each analysis period.

In one embodiment, the line feature data include current data, resistance data, inductance data and steepness data;
the determining a voltage intensity coefficient of the analysis period for each analysis period according to the line feature data of the analysis period comprises:
obtaining an impulse overvoltage of each thunderstorm activity in the analysis period for each analysis period according to the current data, the resistance data, the inductance data and the steepness data in each thunderstorm activity process;
taking an impulse overvoltage with the largest value in the impulse overvoltage in each analysis period as an overvoltage performance value of the analysis period;
performing mean calculation on each impulse overvoltage in each analysis period so as to obtain an overvoltage mean of the analysis period;
performing variance calculation on each impulse overvoltage in each analysis period so as to obtain an overvoltage variance of the analysis period; and
obtaining the voltage intensity coefficient of the analysis period according to the overvoltage performance value, the overvoltage mean and the overvoltage variance of each analysis period.

In one embodiment, the obtaining the impulse overvoltage of each thunderstorm activity in the analysis period for each analysis period according to the current data, the resistance data, the inductance data and the steepness data in each thunderstorm activity process, includes:
calculating according to the following equation for each thunderstorm activity so as to obtain the impulse overvoltage of the thunderstorm activity:

$$U d = I \times R i e + L \times D D$$

In the equation, Ud is the impulse overvoltage, I is the current data, Rie is the resistance data, L is the inductance data, and DD is the steepness data.

In one embodiment, the obtaining the voltage intensity coefficient of the analysis period according to the overvoltage performance value, the overvoltage mean and the overvoltage variance of each analysis period, includes:
calculating according to the following expression for each analysis period so as to obtain the intensity coefficient:

$$QD = {α}_{1} \times YB + {α}_{2} \times YP + {α}_{3} \times Y C$$

In the expression, QD is the intensity coefficient, YB is the overvoltage performance value, YP is the overvoltage mean, YC is the overvoltage variance, α₁ is the proportion coefficient of the overvoltage performance value, α₂ is the proportion coefficient of the overvoltage mean, and α₃ is the proportion coefficient α₁>α₂>α₃>1 of the overvoltage variance.

In one embodiment, the determining the thunderstorm activity assessment value of each analysis period according to the thunderstorm intensity value and the voltage intensity coefficient of each analysis period, includes:
calculating according to the following expression for each analysis period so as to obtain the thunderstorm activity assessment value:

$$GL = {β}_{1} \times LB + {β}_{2} \times Q D$$

In the expression, GL is the thunderstorm activity assessment value, LB is the thunderstorm intensity value, QD is the voltage intensity coefficient, β₁ is the proportion coefficient of the thunderstorm intensity value, and β₂ is the proportion coefficient β₁>β₂>1 of the voltage intensity coefficient.

In one embodiment, the method also includes:
comparing the thunderstorm activity assessment value with a first thunderstorm activity assessment threshold and a second thunderstorm activity assessment threshold preset, wherein the first thunderstorm activity assessment threshold is smaller than the second thunderstorm activity assessment threshold;
determining the defense level of a next analysis period as level one if the thunderstorm activity assessment value is greater than or equal to the second thunderstorm activity assessment threshold;
determining the defense level of the next analysis period as level two if the thunderstorm activity assessment value is greater than the first and smaller than the second thunderstorm activity assessment threshold; and
determining the defense level of the next analysis period as level three if the thunderstorm activity assessment value is smaller than or equal to the first thunderstorm activity assessment threshold.

On a second aspect, the present application provides a thunderstorm activity observation and management device applicable to a power transmission channel, including:
a counting result acquisition module, used for acquiring the number of thunderstorm days in each analysis period based on multiple analysis periods preset, and counting and calculating the number of thunderstorm days in each analysis period so as to obtain a counting result, wherein the counting result is used for indicating the numerical discrepancy of the number of thunderstorm days in each analysis period;
a thunderstorm intensity value determination module, used for adjusting the number of thunderstorm days of each analysis period according to the counting result and a preset discrepancy threshold so as to obtain a thunderstorm intensity value of each analysis period, wherein the thunderstorm intensity value is the number of thunderstorm days after adjustment in each analysis period;
a line feature data acquisition module, used for acquiring multiple line feature data of the power transmission channel in each thunderstorm activity process in each analysis period;
a voltage intensity coefficient determination module, used for determining a voltage intensity coefficient of the analysis period for each analysis period according to the line feature data of the analysis period, wherein the voltage intensity coefficient is used for indicating the thunderstorm intensity in the analysis period; and
a thunderstorm activity assessment module, used for determining a thunderstorm activity assessment value of each analysis period according to the thunderstorm intensity value and the voltage intensity coefficient of each analysis period, wherein the thunderstorm activity assessment value is used for determining a defense level.

On a third aspect, the present application provides a storage medium, wherein computer-readable instructions are stored in the storage medium, and when the computer-readable instructions are executed by one or more processors, the steps of the thunderstorm activity observation and management method applicable to the power transmission channel according to any one of embodiments are executed by one or more processors.

On a fourth aspect, the present application provides a thunderstorm activity observation and management system applicable to a power transmission channel, including: a storage module, a frequency analysis module, an intensity monitoring module, an observation and management platform and a period management module,
wherein the observation and management platform is connected with the storage module, the frequency analysis module, the intensity monitoring module and the period management module respectively;
the storage module is used for storing a preset discrepancy threshold and line feature data;
the frequency analysis module is used for acquiring the number of thunderstorm days in each analysis period based on multiple analysis periods preset, and counting and calculating the number of thunderstorm days in each analysis period so as to obtain a counting result, wherein the counting result is used for indicating the numerical discrepancy of the number of thunderstorm days in each analysis period; adjusting the number of thunderstorm days of each analysis period according to the counting result and a discrepancy threshold so as to obtain a thunderstorm intensity value of each analysis period; and transmitting each thunderstorm intensity value to the period management module, wherein the thunderstorm intensity value is the number of thunderstorm days after adjustment in each analysis period;
the intensity monitoring module is used for acquiring multiple line feature data of the power transmission channel in each thunderstorm activity in each analysis period; determining a voltage intensity coefficient of the analysis period for each analysis period according to the line feature data of the analysis period, and transmitting each voltage intensity coefficient to the observation and management platform, wherein the voltage intensity coefficient is used for indicating the thunderstorm intensity in the analysis period;
the observation and management platform is used for transmitting the thunderstorm intensity value and each voltage intensity coefficient to the period management module;
the period management module is used for determining a thunderstorm activity assessment value of each analysis period according to the thunderstorm intensity value and the voltage intensity coefficient of each analysis period, wherein the thunderstorm activity assessment value is used for determining a defense level.

The technical solutions above show that the present application has the following advantages:

The present application provides a thunderstorm activity observation and management system and method applicable to a power transmission channel. The method includes: counting the number of thunderstorm days acquired in each analysis period based on multiple analysis periods preset, and counting and calculating the number of thunderstorm days of each analysis period so as to obtain a counting result, wherein the counting result is used for indicating the numerical discrepancy of the number of thunderstorm days of each analysis period; adjusting the number of thunderstorm days of each analysis period according to the counting result and a preset discrepancy threshold so as to obtain a thunderstorm intensity value of each analysis period, wherein the thunderstorm intensity value is the number of thunderstorm days after adjustment in each analysis period; obtaining multiple line feature data of the power transmission channel in each thunderstorm activity process in each analysis period; determining a voltage intensity coefficient of the analysis period for each analysis period according to each line feature data of the analysis period, wherein the voltage intensity coefficient is used for indicating the thunderstorm intensity in the analysis period; and determining a thunderstorm activity assessment value of each analysis period according to the thunderstorm intensity value and the voltage intensity coefficient of the analysis period, wherein the thunderstorm activity assessment value is used for determining a defense level. By determining the thunderstorm intensity value of each analysis period, the precision of thunderstorm frequency analysis result can be improved; the thunderstorm intensity in the analysis period is fed back through the value of the voltage intensity coefficient, thereby providing data support for defense level marking of a next analysis period; and through comprehensive analysis with the combination of the thunderstorm intensity value and the intensity coefficient, the defense level is determined according to the thunderstorm activity assessment value, so that the defense resources can be scientifically allocated according to the defense level, and the overall thunderstorm defense effect can be further improved.

### BRIEF DESCRIPTION OF DRAWINGS

In order to describe the technical solutions in the embodiments of the present application or in the prior art more clearly, a brief description of the accompanying drawings required in the embodiments or the prior art will be provided below. Obviously, the accompanying drawings in the following description show merely some embodiments of the present application. Those of ordinary skill in the art can also derive other accompanying drawings from these accompanying drawings without making creative efforts.

FIG. 1 is one of process diagrams of a thunderstorm activity observation and management method applicable to a power transmission channel provided by an embodiment of the present application;

FIG. 2 is a process diagram of determining a thunderstorm intensity value provided by an embodiment of the present application;

FIG. 3 is a process diagram of determining a voltage intensity coefficient provided by an embodiment of the present application;

FIG. 4 is a second process diagram of a thunderstorm activity observation and management method applicable to a power transmission channel provided by embodiments of the present application;

FIG. 5 is a structural schematic diagram of a thunderstorm activity observation and management device applicable to a power transmission channel provided by an embodiment of the present application; and

FIG. 6 is a structural schematic diagram of a thunderstorm activity observation and management system applicable to a power transmission channel provided by an embodiment of the present application.

### DETAILED DESCRIPTION OF THE EMBODIMENTS

The technical solutions in the embodiments of the present application are clearly and completely described below in conjunction with the accompanying drawings in the embodiments of the present application. Apparently, the embodiments described are only a part rather than all of the embodiments of the present application. On the basis of the embodiments in the present application, all other embodiments acquired by those of ordinary skill in the art without creative efforts fall within a protection scope of the present application.

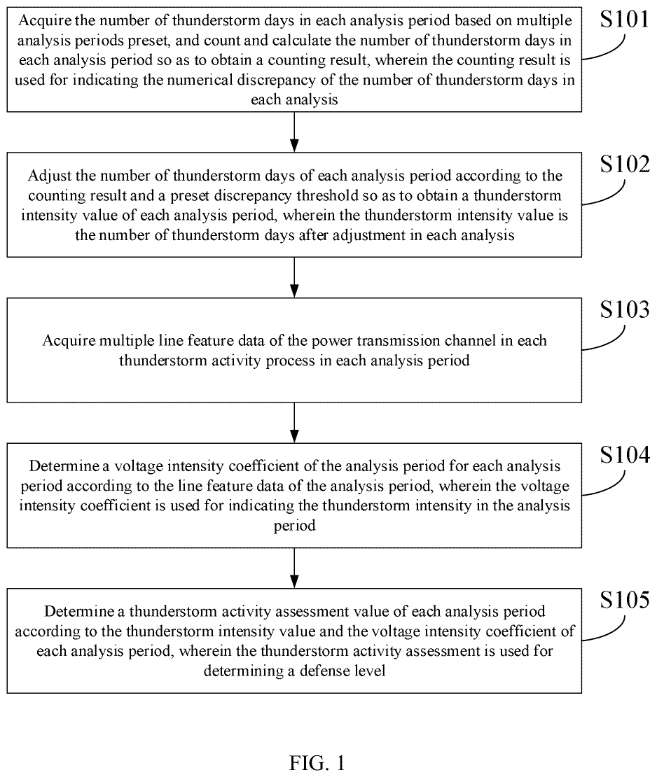

The present application provides a thunderstorm activity observation and management method applicable to a power transmission channel. The following embodiments illustrate the method applied to computer devices. It should be understood that computer devices can be various devices with data processing capabilities, and can include, but are not limited to, a single server, a server cluster, a personal laptop, a desktop computer, and the like. As shown in FIG. 1, the thunderstorm activity observation and management system applicable to the power transmission channel of the present application may includes the following steps:

S101: acquiring the number of thunderstorm days in each analysis period based on multiple analysis periods preset, and counting and calculating the number of thunderstorm days in each analysis period so as to obtain a counting result, wherein the counting result is used for indicating the numerical discrepancy of the number of thunderstorm days in each analysis period.

In the step, in response to a thunderstorm activity risk prediction signal of the power transmission channel, according to the analysis period preset, the number of thunderstorm days in multiple analysis periods is obtained, then the number of thunderstorm days can be combined into a thunderstorm value set, and the thunderstorm value set is counted and calculated, so as to obtain a counting result indicating the numerical discrepancy of the number of thunderstorm days of each analysis period. It can be understood that if the value of the counting result is high, the difference of the number of thunderstorm days of different analysis periods is large, and if the value of the counting result is low, the difference of the number of thunderstorm days of different analysis periods is small. The number of analysis periods can be determined according to actual situations, which is not specifically limited in the present application.

Furthermore, the analysis period refers to a time range for counting the number of thunderstorm days, the analysis period can be determined according to actual situations, which is not specifically limited in the present application, such as one month, one quarter or one year. A thunderstorm day refers to a natural day with thunderstorm activities. The method for obtaining the number of thunderstorm days in each analysis period can be selected based on actual situations, which is not specifically limited in the present application. For example, in each analysis period, the days with thunderstorm activities can be marked as 1, and the days without thunderstorm activities can be marked as 0. By counting the thunderstorm days marked as 1 in the analysis period, the number of thunderstorm days in the analysis period can be obtained. Counting and calculating the number of thunderstorm days of each analysis period refers to counting the change amplitude of values of the numbers of thunderstorm days of each analysis period, the counting and calculating mode can be selected according to actual situations, which is not specifically limited in the present application, such as variance, standard or mean absolute variance.

S102: adjusting the number of thunderstorm days of each analysis period according to the counting result and a preset discrepancy threshold so as to obtain a thunderstorm intensity value of each analysis period, wherein the thunderstorm intensity value is the number of thunderstorm days after adjustment in each analysis period.

In the step, by comparing the counting result and the value of the discrepancy threshold, the numbers of thunderstorm days of each analysis period is adjusted, and through adjustment, the number of thunderstorm days of each analysis cycle can more meet the expectation. The adjustment mode can be selected according to actual situations, which is not specifically limited in the present application. For example, in case of a small number of thunderstorm days of an analysis period, adjustment of adding certain days can be performed according to historical data or relevant indexes; in case of a large number of thunderstorm days of the analysis period, adjustment of reducing the days can be performed according to historical data or relevant indexes; and if the thunderstorm intensity value of the analysis period is within the range of the discrepancy threshold, adjustment can be performed using an interpolation method, to be smooth and balanced. The number of thunderstorm days after adjustment is taken as the thunderstorm intensity value of each analysis period, and the thunderstorm intensity value can be used to reflecting the intensity of thunderstorm activities in each analysis period.

S103: acquiring multiple line feature data of the power transmission channel in each thunderstorm activity process in each analysis period.

In the step, first, the process of thunderstorm activities in each analysis period is marked as a monitoring process, and multiple line feature data of the power transmission channel in the monitoring process is acquired. Line feature data refer to line feature parameters for reflecting thunderstorm activities. For example, line features can be current, voltage, frequency, power and the like of the power transmission channel, and line feature parameters can be maximum current, minimum voltage, power variation, and the like.

Furthermore, line feature data can be directly acquired from corresponding line databases or line data files. Line data in the line databases or line data files can be acquired in each analysis period. When thunderstorm activities occur, line feature data are acquired in real time through installed devices or sensor, thereby ensuring the accuracy and stability of the data acquisition process, and ensuring that the obtained line feature data are reliable. For data acquisition, appropriate devices can be selected according to desired line feature data, such as sensors, instruments or monitoring equipment.

S104: determining a voltage intensity coefficient of the analysis period for each analysis period according to the line feature data of the analysis period, wherein the voltage intensity coefficient is used for indicating the thunderstorm intensity in the analysis period.

In the step, in each analysis period, the voltage intensity coefficient of the thunderstorm intensity in the analysis period for the analysis period can be obtained by calculating the line feature data in the analysis period. It can be understood that if the voltage intensity coefficient is high in value, the voltage intensity in the analysis period is high, and if the voltage intensity coefficient is low in value, the voltage intensity in the analysis period is low.

Furthermore, before calculating the line feature data, processing of data cleaning and transition can be performed on the line feature data, thereby ensuring the accuracy of the line feature data. The calculation mode for the line feature data can be selected according to actual situations, which is not specifically limited in the present application. An initial result obtained through calculation on the line feature data can be modified, and a modified result can be taken as the voltage intensity coefficient. A modification mode can be selected according to actual situations, which is not specifically limited in the present application. For example, modification can be performed using a deep learning model, or through comparison of historical data.

S105: determining a thunderstorm activity assessment value of each analysis period according to the thunderstorm intensity value and the voltage intensity coefficient of each analysis period, wherein the thunderstorm activity assessment is used for determining a defense level.

In the step, in each analysis period, the thunderstorm activity assessment value of the analysis period can be obtained by calculating the thunderstorm intensity value and the voltage intensity coefficient. The calculation mode can be determined according to actual situations. According to the thunderstorm activity assessment value of each analysis period, the thunderstorm activity risk probability of a next analysis period can be deduced in modes of historical data comparison, prediction of deep learning models, counting methods, and the like. The higher the thunderstorm activity risk probability, the more the defense resources are needed, and the lower the thunderstorm activity risk probability, the less the defense resources are needed.

Furthermore, the defense level can be customized according to actual situations, which is not specifically limited in the present application, such as level one, level two and level three, or a high risk, a medium risk and a low risk. It can be understood that each defense level represents different resources, which can be matched with defense resources corresponding to each defense level and defense resources corresponding to thunderstorm activity risk probabilities. For example, a high risk defense level corresponds to most defense resources. If the next analysis period has a high thunderstorm activity risk probability, and the high thunderstorm activity risk probability corresponds to the most defense resources, then the high thunderstorm activity risk probability is matched with the high risk defense level, thereby obtaining the defense level of the next analysis period.

The present application provides a thunderstorm activity observation and management system and method applicable to a power transmission channel. The method includes: counting the number of thunderstorm days acquired in each analysis period based on multiple analysis periods preset, and counting and calculating the number of thunderstorm days of each analysis period so as to obtain a counting result, wherein the counting result is used for indicating the numerical discrepancy of the number of thunderstorm days of each analysis period; adjusting the number of thunderstorm days of each analysis period according to the counting result and a preset discrepancy threshold so as to obtain a thunderstorm intensity value of each analysis period, wherein the thunderstorm intensity value is the number of thunderstorm days after adjustment in each analysis period; obtaining multiple line feature data of the power transmission channel in each thunderstorm activity process in each analysis period; determining a voltage intensity coefficient of the analysis period for each analysis period according to each line feature data of the analysis period, wherein the voltage intensity coefficient is used for indicating the thunderstorm intensity in the analysis period; and determining a thunderstorm activity assessment value of each analysis period according to the thunderstorm intensity value and the voltage intensity coefficient of the analysis period, wherein the thunderstorm activity assessment value is used for determining a defense level. By determining the thunderstorm intensity value of each analysis period, the precision of thunderstorm frequency analysis result can be improved; the thunderstorm intensity in the analysis period is fed back through the value of the voltage intensity coefficient, thereby providing data support for defense level marking of a next analysis period; and through comprehensive analysis with the combination of the thunderstorm intensity value and the intensity coefficient, the defense level is determined according to the thunderstorm activity assessment value, so that the defense resources can be scientifically allocated according to the defense level, and the overall thunderstorm defense effect can be further improved.

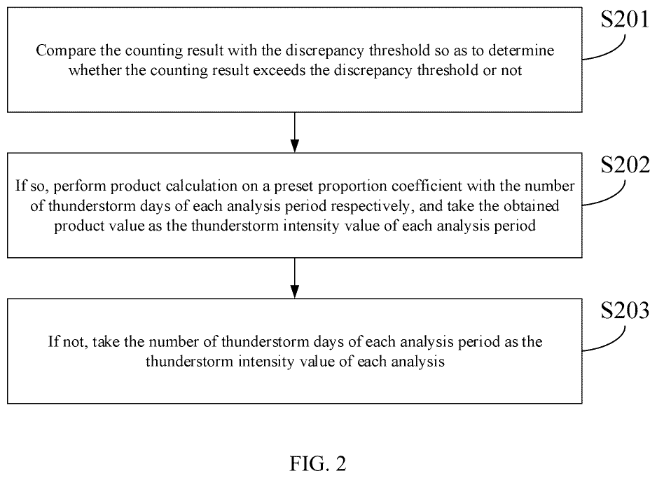

As shown in FIG. 2, in one embodiment, adjusting the number of thunderstorm days of each analysis period according to the counting result and a preset discrepancy threshold so as to obtain a thunderstorm intensity value of each analysis period includes:
S201: comparing the counting result with the discrepancy threshold so as to determine whether the counting result exceeds the discrepancy threshold or not;
S202: if so, performing product calculation on a preset proportion coefficient with the number of thunderstorm days of each analysis period respectively, and taking the obtained product value as the thunderstorm intensity value of each analysis period;
S203: if not, taking the number of thunderstorm days of each analysis period as the thunderstorm intensity value of each analysis period.

Specifically, the counting result is compared with the discrepancy threshold to judge whether the counting result exceeds the discrepancy threshold or not. If so, the numerical difference of the number of thunderstorm days of each analysis period is too large. A proportion coefficient preset is multiplied with the number of thunderstorm days of each analysis period, and the product result is taken as the thunderstorm intensity value of each analysis period. The value range of the proportion coefficient can be selected according to actual situations, which is not specifically limited in the present application. For example, the value range can be greater than or equal to 1.25, and smaller than or equal to 1.35. If not, the numerical difference of the number of thunderstorm days of each analysis period is small, and then the number of thunderstorm days of each analysis period is taken as the thunderstorm intensity value of each analysis period, so that the thunderstorm value determination process is simplified, and the efficiency of thunderstorm value calculation is improved.

It can be understood that the thunderstorm value of the analysis period is obtained by counting the number of thunderstorm days in the analysis period, and the thunderstorm value of the analysis period is further adjusted according to the numerical fluctuation degree of the thunderstorm value of multiple recent analysis periods so as to obtain the thunderstorm intensity value, so that the precision of the thunderstorm frequency analysis result can be improved.

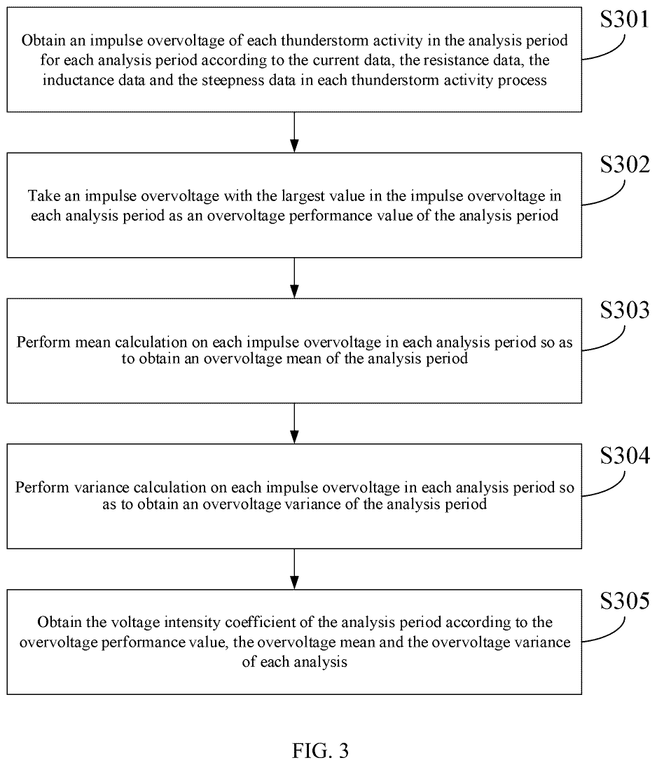

As shown in FIG. 3, in one embodiment, the line feature data include current data, resistance data, inductance data and steepness data.
the determining a voltage intensity coefficient of the analysis period for each analysis period according to the line feature data of the analysis period comprises:
S301: obtaining an impulse overvoltage of each thunderstorm activity in the analysis period for each analysis period according to the current data, the resistance data, the inductance data and the steepness data in each thunderstorm activity process;
S302: taking an impulse overvoltage with the largest value in the impulse overvoltage in each analysis period as an overvoltage performance value of the analysis period;
S303: performing mean calculation on each impulse overvoltage in each analysis period so as to obtain an overvoltage mean of the analysis period;
S304: performing variance calculation on each impulse overvoltage in each analysis period so as to obtain an overvoltage variance of the analysis period; and
S305: obtaining the voltage intensity coefficient of the analysis period according to the overvoltage performance value, the overvoltage mean and the overvoltage variance of each analysis period.

Specifically, the line feature data include current data, resistance data, inductance data and steepness data. The current data is a thunderstorm current value. The steepness data is an impulse grounding resistance value of an anti-thunder grounding device. The inductance data is an inductance value of a thunderstorm current path. The steepness data is a thunderstorm current steepness value. The impulse overvoltage of each thunderstorm activity in the analysis period for each analysis period can be obtained according to the current data, the resistance data, the inductance data and the steepness data in each thunderstorm activity process. The maximum value of the impulse overvoltage in all thunderstorm activity processes in the analysis period is marked as the overvoltage performance value, the impulse overvoltage in all thunderstorm activity processes in the analysis period is summed and averaged so as to obtain the overvoltage mean, and variance calculation is performed on the impulse overvoltage in the thunderstorm activity process in the analysis period so as to obtain the overvoltage variance. The voltage intensity coefficient of the analysis period can be obtained according to the overvoltage performance value, the overvoltage mean and the overvoltage variance of each analysis period. The calculation mode for the impulse overvoltage and the voltage intensity coefficient can be selected according to actual situations, which is not specifically limited in the present application.

It can be understood that the impulse overvoltage is obtained by analyzing and calculating line feature parameters in the thunderstorm activity, and then the impulse overvoltage of all thunderstorm activities in the analysis period are counted and calculated so as to obtain the voltage intensity coefficient. The thunderstorm intensity in the analysis period is fed back through the value of the voltage intensity coefficient, to provide data support for defense level marking in the next analysis period.

In one embodiment, the obtaining the impulse overvoltage of each thunderstorm activity in the analysis period for each analysis period according to the current data, the resistance data, the inductance data and the steepness data in each thunderstorm activity process, includes:
calculating according to the following equation for each thunderstorm activity so as to obtain the impulse overvoltage of the thunderstorm activity:

$$U d = I \times R i e + L \times D D$$

In the equation, Ud is the impulse overvoltage, I is the current data, Rie is the resistance data, L is the inductance data, and DD is the steepness data.

In one embodiment, the obtaining the voltage intensity coefficient of the analysis period according to the overvoltage performance value, the overvoltage mean and the overvoltage variance of each analysis period, includes:
calculating according to the following expression for each analysis period so as to obtain the intensity coefficient:

$$QD = {α}_{1} \times YB + {α}_{2} \times YP + {α}_{3} \times Y C$$

In the expression, QD is the intensity coefficient, YB is the overvoltage performance value, YP is the overvoltage mean, YC is the overvoltage variance, α₁ is the proportion coefficient of the overvoltage performance value, α₂ is the proportion coefficient of the overvoltage mean, and α₃ is the proportion coefficient α₁>α₂>α₃>1 of the overvoltage variance.

In one embodiment, the determining the thunderstorm activity assessment value of each analysis period according to the thunderstorm intensity value and the voltage intensity coefficient of each analysis period, includes:
calculating according to the following expression for each analysis period so as to obtain the thunderstorm activity assessment value:

$$GL = {β}_{1} \times LB + {β}_{2} \times Q D$$

In the expression, GL is the thunderstorm activity assessment value, LB is the thunderstorm intensity value, QD is the voltage intensity coefficient, β₁ is the proportion coefficient of the thunderstorm intensity value, and β₂ is the proportion coefficient β₁>β₂>1 of the voltage intensity coefficient.

Specifically, the specific value of the proportion coefficient in the equation above can be determined according to actual situations. For example, multiple groups of sample data can be collected, corresponding initial coefficients can be set for each group of sample data, the set initial coefficients and the collected sample data are put into the equations, any three equations form a system of three linear equations in three variables, the coefficients obtained through calculation are screened and averaged, and then values of α₁, α₂ and α₃ are 3.45, 2.68 and 2.17.

It can be understood that the value of the proportion coefficient is to quantify the parameters to obtain a specific value which is convenient to later comparison. The value of the proportion coefficient dents on the volume of the sample data and the corresponding initial coefficient primarily set by the person skilled in the art for each group of sample data, as long as that the proportion relationship between the parameters and the quantified values is not affected, for example, the initial coefficient is directly proportional to the value of the overvoltage performance value.

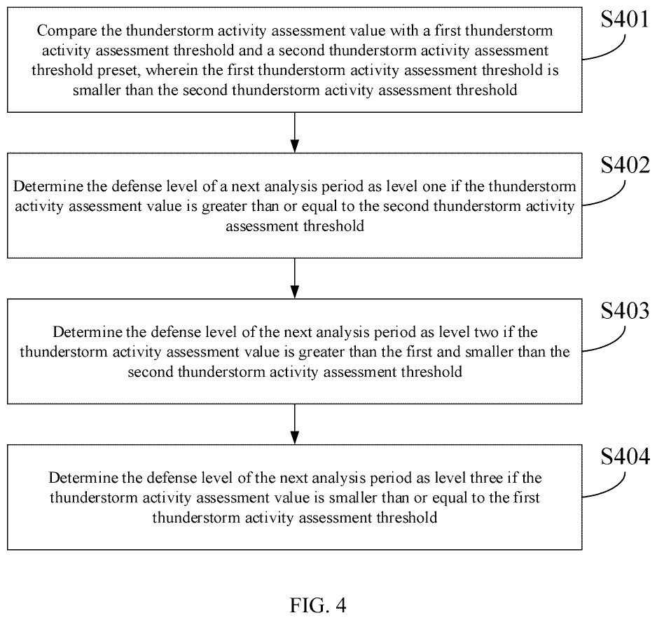

As shown in FIG. 4, in one of the embodiments, the method also includes:
S401: comparing the thunderstorm activity assessment value with a first thunderstorm activity assessment threshold and a second thunderstorm activity assessment threshold preset, wherein the first thunderstorm activity assessment threshold is smaller than the second thunderstorm activity assessment threshold;
S402: determining the defense level of a next analysis period as level one if the thunderstorm activity assessment value is greater than or equal to the second thunderstorm activity assessment threshold;
S403: determining the defense level of the next analysis period as level two if the thunderstorm activity assessment value is greater than the first and smaller than the second thunderstorm activity assessment threshold; and
S404: determining the defense level of the next analysis period as level three if the thunderstorm activity assessment value is smaller than or equal to the first thunderstorm activity assessment threshold.

It can be understood that the thunderstorm activity assessment value is compared with the preset threshold, the defense level of the next analysis period is determined according to different conditions, then the risk degree of the thunderstorm activity can be assessed, corresponding defense measures can be taken according to needs, and the defense resources are scientifically allocated, so that the overall thunderstorm defense effect can be improved.

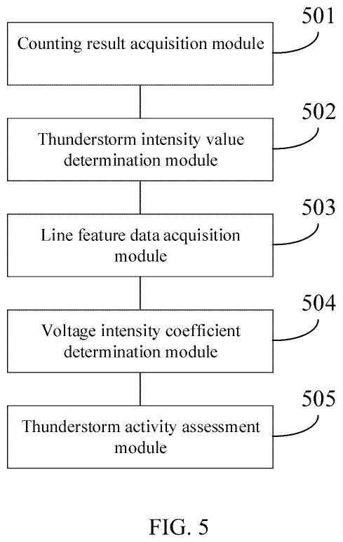

The thunderstorm activity observation and management device applicable to the power transmission channel provided by the embodiment of the present application is described below. The thunderstorm activity observation and management device applicable to the power transmission channel described below and the thunderstorm activity observation and management method applicable to the power transmission channel described above can correspond and refer to each other. As shown in FIG. 5, the thunderstorm activity observation and management device applicable to the power transmission channel provided by the present application may includes the following structure:
a counting result acquisition module 501, used for acquiring the number of thunderstorm days in each analysis period based on multiple analysis periods preset, and counting and calculating the number of thunderstorm days in each analysis period so as to obtain a counting result, wherein the counting result is used for indicating the numerical discrepancy of the number of thunderstorm days in each analysis period;
a thunderstorm intensity value determination module 502, used for adjusting the number of thunderstorm days of each analysis period according to the counting result and a preset discrepancy threshold so as to obtain a thunderstorm intensity value of each analysis period, wherein the thunderstorm intensity value is the number of thunderstorm days after adjustment in each analysis period;
a line feature data acquisition module 503, used for acquiring multiple line feature data of the power transmission channel in each thunderstorm activity process in each analysis period;
a voltage intensity coefficient determination module 504, used for determining a voltage intensity coefficient of the analysis period for each analysis period according to the line feature data of the analysis period, wherein the voltage intensity coefficient is used for indicating the thunderstorm intensity in the analysis period; and
a thunderstorm activity assessment module 505, used for determining a thunderstorm activity assessment value of each analysis period according to the thunderstorm intensity value and the voltage intensity coefficient of each analysis period, wherein the thunderstorm activity assessment value is used for determining a defense level.

In one embodiment, thunderstorm intensity value determination module 502 includes:
a value comparing unit, used for comparing the counting result with the discrepancy threshold so as to determine whether the counting result exceeds the discrepancy threshold or not;
a first thunderstorm intensity value determination unit, used for if so, performing product calculation on a preset proportion coefficient with the number of thunderstorm days of each analysis period respectively, and taking the obtained product value as the thunderstorm intensity value of each analysis period;
a second thunderstorm intensity value determination unit, used for if not, taking the number of thunderstorm days of each analysis period as the thunderstorm intensity value of each analysis period.

In one embodiment, the line feature data include current data, resistance data, inductance data and steepness data;

The voltage intensity coefficient determination module 504 includes:
an impulse overvoltage determination unit, used for obtaining an impulse overvoltage of each thunderstorm activity in the analysis period for each analysis period according to the current data, the resistance data, the inductance data and the steepness data in each thunderstorm activity process;
an overvoltage performance value determination unit, used for taking an impulse overvoltage with the largest value in the impulse overvoltage in each analysis period as an overvoltage performance value of the analysis period;
an overvoltage mean determination unit, used for performing mean calculation on each impulse overvoltage in each analysis period so as to obtain an overvoltage mean of the analysis period;
an overvoltage variance determination unit, used for performing variance calculation on each impulse overvoltage in each analysis period so as to obtain an overvoltage variance of the analysis period; and
a voltage intensity coefficient determination unit, used for obtaining the voltage intensity coefficient of the analysis period according to the overvoltage performance value, the overvoltage mean and the overvoltage variance of each analysis period.

In one embodiment, the impulse overvoltage determination module includes:
an impulse overvoltage calculation subunit, used for calculating according to the following equation for each thunderstorm activity so as to obtain the impulse overvoltage of the thunderstorm activity:

$$U d = I \times R i e + L \times D D$$

In the equation, Ud is the impulse overvoltage, I is the current data, Rie is the resistance data, L is the inductance data, and DD is the steepness data.

In one embodiment, the voltage intensity coefficient determination unit includes:
a voltage intensity coefficient calculation subunit, used for calculating according to the following expression for each analysis period so as to obtain the intensity coefficient:

$$QD = {α}_{1} \times YB + {α}_{2} \times YP + {α}_{3} \times Y C$$

In the expression, QD is the intensity coefficient, YB is the overvoltage performance value, YP is the overvoltage mean, YC is the overvoltage variance, α₁ is the proportion coefficient of the overvoltage performance value, α₂ is the proportion coefficient of the overvoltage mean, and α₃ is the proportion coefficient α₁>α₂>α₃>1 of the overvoltage variance.

In one embodiment, the thunderstorm activity assessment module 505 includes:
a thunderstorm activity assessment value calculation unit, used for calculating according to the following expression for each analysis period so as to obtain the thunderstorm activity assessment value:

$$GL = {β}_{1} \times LB + {β}_{2} \times Q D$$

In the expression, GL is the thunderstorm activity assessment value, LB is the thunderstorm intensity value, QD is the voltage intensity coefficient, β₁ is the proportion coefficient of the thunderstorm intensity value, and β₂ is the proportion coefficient β₁>β₂>1 of the voltage intensity coefficient.

In one embodiment, the device also includes:
a value comparing module, used for comparing the thunderstorm activity assessment value with a first thunderstorm activity assessment threshold and a second thunderstorm activity assessment threshold preset, wherein the first thunderstorm activity assessment threshold is smaller than the second thunderstorm activity assessment threshold;
a first defense level determination module, used for determining the defense level of a next analysis period as level one if the thunderstorm activity assessment value is greater than or equal to the second thunderstorm activity assessment threshold;
a second defense level determination module, used for determining the defense level of the next analysis period as level two if the thunderstorm activity assessment value is greater than the first and smaller than the second thunderstorm activity assessment threshold; and
a third defense level determination module, used for determining the defense level of the next analysis period as level three if the thunderstorm activity assessment value is smaller than or equal to the first thunderstorm activity assessment threshold.

In one embodiment, the present application also provides a storage medium, wherein computer-readable instructions are stored in the storage medium, and when the computer-readable instructions are executed by one or more processors, the steps of the thunderstorm activity observation and management method applicable to the power transmission channel according to any one of the claims are executed by one or more processors.

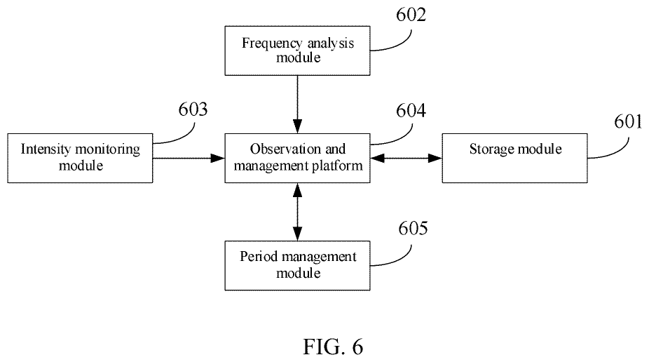

As shown in FIG. 6, in one embodiment, the present application provides a thunderstorm activity observation and management system applicable to a power transmission channel, including: a storage module 601, a frequency analysis module 602, an intensity monitoring module 603, an observation and management platform 604 and a period management module 605,
wherein the observation and management platform 604 is connected with the storage module 601, the frequency analysis module 602, the intensity monitoring module 603 and the period management module 605 respectively;
the storage module 601 is used for storing a preset discrepancy threshold and line feature data;
the frequency analysis module 602 is used for acquiring the number of thunderstorm days in each analysis period based on multiple analysis periods preset, and counting and calculating the number of thunderstorm days in each analysis period so as to obtain a counting result, wherein the counting result is used for indicating the numerical discrepancy of the number of thunderstorm days in each analysis period; adjusting the number of thunderstorm days of each analysis period according to the counting result and a discrepancy threshold so as to obtain a thunderstorm intensity value of each analysis period; and transmitting each thunderstorm intensity value to the period management module 604, wherein the thunderstorm intensity value is the number of thunderstorm days after adjustment in each analysis period;
the intensity monitoring module 603 is used for acquiring multiple line feature data of the power transmission channel in each thunderstorm activity in each analysis period;
determining a voltage intensity coefficient of the analysis period for each analysis period according to the line feature data of the analysis period, and transmitting each voltage intensity coefficient to the observation and management platform 604, wherein the voltage intensity coefficient is used for indicating the thunderstorm intensity in the analysis period;
the observation and management platform 604 is used for transmitting the thunderstorm intensity value and each voltage intensity coefficient to the period management module 605;
the period management module 605 is used for determining a thunderstorm activity assessment value of each analysis period according to the thunderstorm intensity value and the voltage intensity coefficient of each analysis period, wherein the thunderstorm activity assessment value is used for determining a defense level.

Specifically, the observation and management platform can be in communication connection with the storage module, the frequency analysis module, the intensity monitoring module and the period management module, and the observation and management platform can be in bidirectional connection with the storage module and the period management module respectively. The frequency analysis module can acquire the discrepancy threshold from the storage module through the observation and management platform. The intensity monitoring module can acquire the line feature data from the storage module through the observation and management platform. After receiving the thunderstorm intensity value transmitted from the frequency analysis module and the voltage intensity coefficient transmitted from the intensity monitoring module, the observation and management platform transmits the thunderstorm intensity value and the voltage intensity coefficient to the period management module, and the period management module determines the thunderstorm activity assessment value of each analysis period according to received thunderstorm intensity value and voltage intensity coefficient, to determine the defense level according to the thunderstorm activity assessment value.

Furthermore, the frequency analysis module obtains the number of thunderstorm days in each analysis based on multiple analysis periods preset, and counts and calculates the number of thunderstorm days of each analysis period so as to obtain a counting result, wherein the counting result is used for indicating the numerical discrepancy of the number of thunderstorm days of each analysis period; and adjusts the number of thunderstorm days of each analysis period according to the counting result and a discrepancy threshold preset so as to obtain a thunderstorm intensity value of each analysis period, wherein the thunderstorm intensity value is the number of thunderstorm days after adjustment in each analysis period; the intensity monitoring module obtains multiple line feature data of the power transmission channel in each thunderstorm activity process in each analysis period; and determines a voltage intensity coefficient of the analysis period for each analysis period according to each line feature data of the analysis period, wherein the voltage intensity coefficient is used for indicating the thunderstorm intensity in the analysis period; and the period management module determines a thunderstorm activity assessment value of each analysis period according to the thunderstorm intensity value and the voltage intensity coefficient of the analysis period, wherein the thunderstorm activity assessment value is used for determining a defense level.

It can be understood that by determining the thunderstorm intensity value of each analysis period, the precision of thunderstorm frequency analysis result can be improved; the thunderstorm intensity in the analysis period is fed back through the value of the voltage intensity coefficient, thereby providing data support for defense level marking of a next analysis period; and through comprehensive analysis with the combination of the thunderstorm intensity value and the intensity coefficient, the defense level is determined according to the thunderstorm activity assessment value, so that the defense resources can be scientifically allocated according to the defense level, and the overall thunderstorm defense effect can be further improved.

Finally, it should be noted that in the specification, relational terms such as first and second are merely used to distinguish one entity or operation from another, and do not necessarily imply or suggest any actual relationship or sequence between these entities or operations. Furthermore, the terms “include”, “comprise”, or any variants thereof are intended to cover a non-exclusive inclusion, so that a process, method, article, or equipment that includes a series of elements not only includes those elements, but also includes other elements not listed explicitly, or includes inherent elements of the process, method, article, or equipment. In the absence of any further restrictions, the elements limited by the statement “including one . . . ” do not rule out the possibility that there may be other identical elements in the process, method, item or device that includes the aforementioned elements. In the specification, “one”, “an”, “the”, “that”, and “thereof” can also be in plural form, unless the context clearly indicates otherwise. Multiple refers to the situation of at least two, such as two, three, five or eight. “Or/and” includes any and all combinations of the listed items.

The embodiments in the specification are described in a progressive manner. Each embodiment focuses on highlighting the differences from the other embodiments. The embodiments can be combined as needed, and the same or similar parts can be referred to for comparison.

The above description of the disclosed embodiments enables those skilled in the art to implement or use the present application. Various modifications to these embodiments will be apparent to those skilled in the art. The general principles defined herein can be implemented in other embodiments without departing from the spirit or scope of the present application. Therefore, the present application is not be limited to the specific embodiments shown in the specification, but instead conforms to the broadest scope that is consistent with the principles and features disclosed in the specification.

What is claimed is:

1. A thunderstorm activity observation and management method applicable to a power transmission channel, comprising:
acquiring the number of thunderstorm days in each analysis period based on multiple analysis periods preset, and counting and calculating the number of thunderstorm days in each analysis period so as to obtain a counting result, wherein the counting result is used for indicating the numerical discrepancy of the number of thunderstorm days in each analysis period;
adjusting the number of thunderstorm days of each analysis period according to the counting result and a preset discrepancy threshold so as to obtain a thunderstorm intensity value of each analysis period, wherein the thunderstorm intensity value is the number of thunderstorm days after adjustment in each analysis period;
acquiring multiple line feature data of the power transmission channel in each thunderstorm activity process in each analysis period;
determining a voltage intensity coefficient of the analysis period for each analysis period according to the line feature data of the analysis period, wherein the voltage intensity coefficient is used for indicating the thunderstorm intensity in the analysis period; and
determining a thunderstorm activity assessment value of each analysis period according to the thunderstorm intensity value and the voltage intensity coefficient of each analysis period, wherein the thunderstorm activity assessment is used for determining a defense level.

2. The thunderstorm activity observation and management method applicable to the power transmission channel according to claim 1, wherein the adjusting the number of thunderstorm days of each analysis period according to the counting result and a preset discrepancy threshold so as to obtain a thunderstorm intensity value of each analysis period comprises:
comparing the counting result with the discrepancy threshold so as to determine whether the counting result exceeds the discrepancy threshold or not;
if so, performing product calculation on a preset proportion coefficient with the number of thunderstorm days of each analysis period respectively, and taking the obtained product value as the thunderstorm intensity value of each analysis period; and
if not, taking the number of thunderstorm days of each analysis period as the thunderstorm intensity value of each analysis period.

3. The thunderstorm activity observation and management method applicable to the power transmission channel according to claim 1, wherein the line feature data comprise current data, resistance data, inductance data and steepness data;
the determining a voltage intensity coefficient of the analysis period for each analysis period according to the line feature data of the analysis period comprises:
obtaining an impulse overvoltage of each thunderstorm activity in the analysis period for each analysis period according to the current data, the resistance data, the inductance data and the steepness data in each thunderstorm activity process;
taking an impulse overvoltage with the largest value in the impulse overvoltage in each analysis period as an overvoltage performance value of the analysis period;
performing mean calculation on each impulse overvoltage in each analysis period so as to obtain an overvoltage mean of the analysis period;
performing variance calculation on each impulse overvoltage in each analysis period so as to obtain an overvoltage variance of the analysis period; and
obtaining the voltage intensity coefficient of the analysis period according to the overvoltage performance value, the overvoltage mean and the overvoltage variance of each analysis period.

4. The thunderstorm activity observation and management method applicable to the power transmission channel according to claim 3, wherein the obtaining an impulse overvoltage of each thunderstorm activity in the analysis period for each analysis period according to the current data, the resistance data, the inductance data and the steepness data in each thunderstorm activity process comprises:
calculating according to the following equation for each thunderstorm activity so as to obtain the impulse overvoltage of the thunderstorm activity:
$$U d = I \times R i e + L \times D D$$
in the equation, Ud is the impulse overvoltage, I is the current data, Rie is the resistance data, L is the inductance data, and DD is the steepness data.

5. The thunderstorm activity observation and management method applicable to the power transmission channel according to claim 3, wherein the obtaining the voltage intensity coefficient of the analysis period according to the overvoltage performance value, the overvoltage mean and the overvoltage variance of each analysis period comprises:
calculating according to the following expression for each analysis period so as to obtain the intensity coefficient:
$$QD = {α}_{1} \times YB + {α}_{2} \times YP + {α}_{3} \times YC$$
in the expression, QD is the intensity coefficient, YB is the overvoltage performance value, YP is the overvoltage mean, YC is the overvoltage variance, α₁ is the proportion coefficient of the overvoltage performance value, α₂ is the proportion coefficient of the overvoltage mean, and α₃ is the proportion coefficient α₁>α₂>α₃>1 of the overvoltage variance.

6. The thunderstorm activity observation and management method applicable to the power transmission channel according to claim 1, wherein the determining the thunderstorm activity assessment value of each analysis period according to the thunderstorm intensity value and the voltage intensity coefficient of each analysis period comprises:
calculating according to the following expression for each analysis period so as to obtain the thunderstorm activity assessment value:
$$GL = {β}_{1} \times LB + {β}_{2} \times QD$$
in the expression, GL is the thunderstorm activity assessment value, LB is the thunderstorm intensity value, QD is the voltage intensity coefficient, β₁ is the proportion coefficient of the thunderstorm intensity value, and β₂ is the proportion coefficient β₁>β₂>1 of the voltage intensity coefficient.

7. The thunderstorm activity observation and management method applicable to the power transmission channel according to claim 6, further comprising:
comparing the thunderstorm activity assessment value with a first thunderstorm activity assessment threshold and a second thunderstorm activity assessment threshold preset, wherein the first thunderstorm activity assessment threshold is smaller than the second thunderstorm activity assessment threshold;
determining the defense level of a next analysis period as level one if the thunderstorm activity assessment value is greater than or equal to the second thunderstorm activity assessment threshold;
determining the defense level of the next analysis period as level two if the thunderstorm activity assessment value is greater than the first and smaller than the second thunderstorm activity assessment threshold; and
determining the defense level of the next analysis period as level three if the thunderstorm activity assessment value is smaller than or equal to the first thunderstorm activity assessment threshold.

8. A thunderstorm activity observation and management device applicable to a power transmission channel, comprising:
a counting result acquisition module, used for acquiring the number of thunderstorm days in each analysis period based on multiple analysis periods preset, and counting and calculating the number of thunderstorm days in each analysis period so as to obtain a counting result, wherein the counting result is used for indicating the numerical discrepancy of the number of thunderstorm days in each analysis period;
a thunderstorm intensity value determination module, used for adjusting the number of thunderstorm days of each analysis period according to the counting result and a preset discrepancy threshold so as to obtain a thunderstorm intensity value of each analysis period, wherein the thunderstorm intensity value is the number of thunderstorm days after adjustment in each analysis period;
a line feature data acquisition module, used for acquiring multiple line feature data of the power transmission channel in each thunderstorm activity process in each analysis period;
a voltage intensity coefficient determination module, used for determining a voltage intensity coefficient of the analysis period for each analysis period according to the line feature data of the analysis period, wherein the voltage intensity coefficient is used for indicating the thunderstorm intensity in the analysis period; and
a thunderstorm activity assessment module, used for determining a thunderstorm activity assessment value of each analysis period according to the thunderstorm intensity value and the voltage intensity coefficient of each analysis period, wherein the thunderstorm activity assessment value is used for determining a defense level.

9. A storage medium, wherein computer-readable instructions are stored in the storage medium, and when the computer-readable instructions are executed by one or more processors, the steps of the thunderstorm activity observation and management method applicable to the power transmission channel according to claim 6 are executed by one or more processors.

10. A thunderstorm activity observation and management system applicable to a power transmission channel, comprising: a storage module, a frequency analysis module, an intensity monitoring module, an observation and management platform and a period management module;
wherein the observation and management platform is connected with the storage module, the frequency analysis module, the intensity monitoring module and the period management module respectively;
the storage module is used for storing a preset discrepancy threshold and line feature data;
the frequency analysis module is used for acquiring the number of thunderstorm days in each analysis period based on multiple analysis periods preset, and counting and calculating the number of thunderstorm days in each analysis period so as to obtain a counting result, wherein the counting result is used for indicating the numerical discrepancy of the number of thunderstorm days in each analysis period; adjusting the number of thunderstorm days of each analysis period according to the counting result and a discrepancy threshold so as to obtain a thunderstorm intensity value of each analysis period; and transmitting each thunderstorm intensity value to the period management module, wherein the thunderstorm intensity value is the number of thunderstorm days after adjustment in each analysis period;
the intensity monitoring module is used for acquiring multiple line feature data of the power transmission channel in each thunderstorm activity in each analysis period; determining a voltage intensity coefficient of the analysis period for each analysis period according to the line feature data of the analysis period, and transmitting each voltage intensity coefficient to the observation and management platform, wherein the voltage intensity coefficient is used for indicating the thunderstorm intensity in the analysis period;
the observation and management platform is used for transmitting the thunderstorm intensity value and each voltage intensity coefficient to the period management module;
the period management module is used for determining a thunderstorm activity assessment value of each analysis period according to the thunderstorm intensity value and the voltage intensity coefficient of each analysis period, wherein the thunderstorm activity assessment value is used for determining a defense level.
